(19) United States
(12) Patent Application Publication
(10) Pub. No.: US 2025/0324829 A1
(43) Pub. Date: Oct. 16, 2025

(54) MICROLED DISPLAY AND METHOD FOR FABRICATION

(71) Applicant: OmniVision Technologies, Inc., Santa Clara, CA (US)

(72) Inventors: Liang ZHAO, Gilroy, CA (US); Hing Mo LAM, Cupertino, CA (US); Regis FAN, Sunnyvale, CA (US)

(21) Appl. No.: 18/637,201

(22) Filed: Apr. 16, 2024

(51) Int. Cl. H01L 33/62; H01L 25/16

(52) U.S. Cl. CPC H10H 20/857; H01L 25/167; H10H 20/0364

(57) ABSTRACT

A micro light-emitting diode (LED) display includes a first pixel, a second pixel, and an opaque conductive element. The first pixel includes a first LED, a third LED, and a first common-interconnection electrically connected to each of the first LED and the third LED. The second pixel includes a second LED, a fourth LED, and a second common-interconnection electrically connected to each of the second LED and the fourth LED. The opaque conductive element is electrically connected to each of the first common-interconnection and the second common-interconnection.

### BACKGROUND

A conventional microLED display panel include an array of pixels covered by a transparent or semi-transparent conductive layer, which functions as a common electrode for each pixel. Due to the layer's sheet resistivity, the layer has a non-uniform voltage across the pixel array, which decreases brightness uniformity and color accuracy.

### SUMMARY OF THE EMBODIMENTS

Embodiments disclosed here remedy the above-mentioned problems with conventional microLED displays.

In a first aspect, a micro light-emitting diode (LED) display is disclosed. The display includes a first pixel, a second pixel, and an opaque conductive element. The first pixel includes a first LED, a third LED, and a first common-interconnection electrically connected to each of the first LED and the third LED. The second pixel includes a second LED, a fourth LED, and a second common-interconnection electrically connected to each of the second LED and the fourth LED. The opaque conductive element is electrically connected to each of the first common-interconnection and the second common-interconnection.

In a second aspect, a method for fabricating an LED pixel-pair is disclosed. The method includes hybrid-bonding a first front-plane layer to a back-plane layer. The first front-plane layer includes (i) a first dielectric layer, (ii) a first LED and a second LED embedded in the first dielectric layer, (iii) a first common-interconnection segment and second common-interconnection segment each spanning a thickness of the first dielectric layer. The method also includes hybrid-bonding a second front-plane layer to a first spacer-dielectric layer located on the first front-plane layer. The second front-plane layer includes (i) a second dielectric layer, (ii) a third LED and a fourth LED embedded in the second dielectric layer and (iii) a third common-interconnection segment and fourth common-interconnection segment each spanning a thickness of the second dielectric layer.

### BRIEF DESCRIPTION OF THE FIGURES

FIG. 1 is a schematic of a light-emitting diode (LED) display that includes an LED array of pixels.

FIGS. 2-4 are respective schematics of a pixel, which is an example of a pixel of the LED array of FIG. 1, in an embodiment.

FIGS. 5A and 5B are respective schematics of a pixel, which is an example of a pixel of the LED array of FIG. 1, in an embodiment.

FIG. 6 illustrates the pixel of FIGS. 5A and 5B surrounded by an opaque isolation wall, in an embodiment.

FIG. 7 is a connectivity diagram of a microLED display, which is an embodiment of the LED display of FIG. 1.

FIGS. 8-21 illustrate respective intermediate structures formed in an embodiment of a method for fabricating the microLED display of FIG. 7.

FIG. 22 is a flowchart illustrating a method for fabricating the microLED display of FIG. 7, in an embodiment.

FIG. 23 is a flowchart of steps that may be included in embodiments of the method of FIG. 22.

### DETAILED DESCRIPTION OF THE EMBODIMENTS

Figures herein depict orthogonal axes A1, A2, and A3. Unless otherwise specified, heights and depths of objects herein refer to the object's extent along axis A3. Also, herein, a horizontal plane is parallel to the A1-A2 plane, a width refers to an object's extent along axis A1 or axis A2, and a vertical direction is along axis A3.

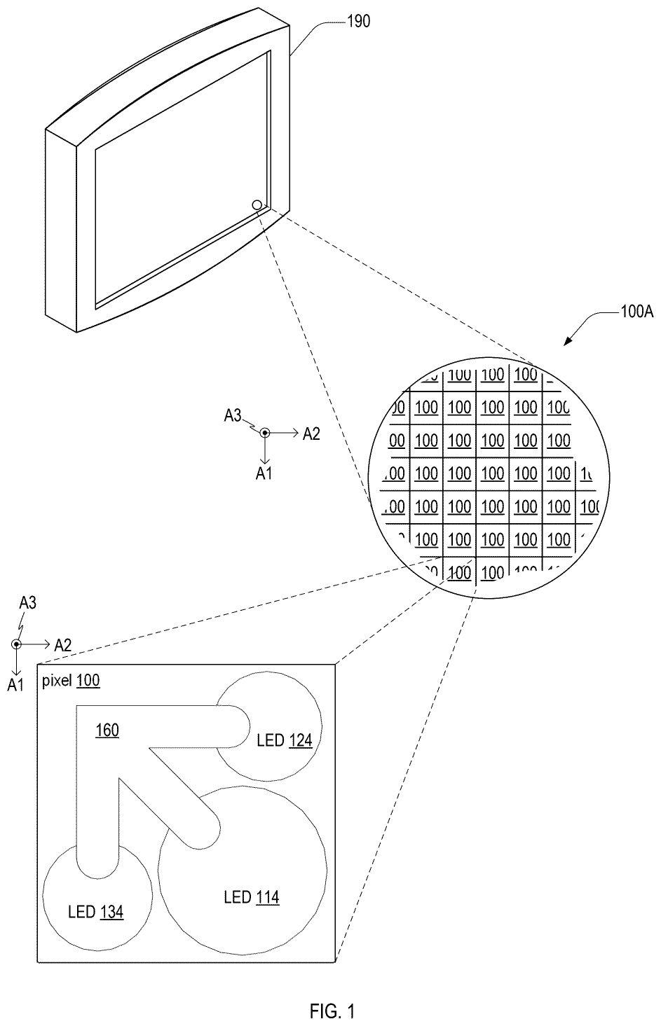

FIG. 1 is a schematic of a light-emitting diode (LED) display 190 that includes an LED array 100A of pixels 100. Each pixel 100 includes an LED 114, an LED 124, and an LED 134, each of which may be a microLED. Pixel 100 also includes a common-interconnection 160 that is electrically connected to each of LEDs 114, 124, and 134. For example, common-interconnection 160 may be electrically connected to either a respective anode of LEDs 114, 124, and 134 or a respective cathode of LEDs 114, 124, and 134.

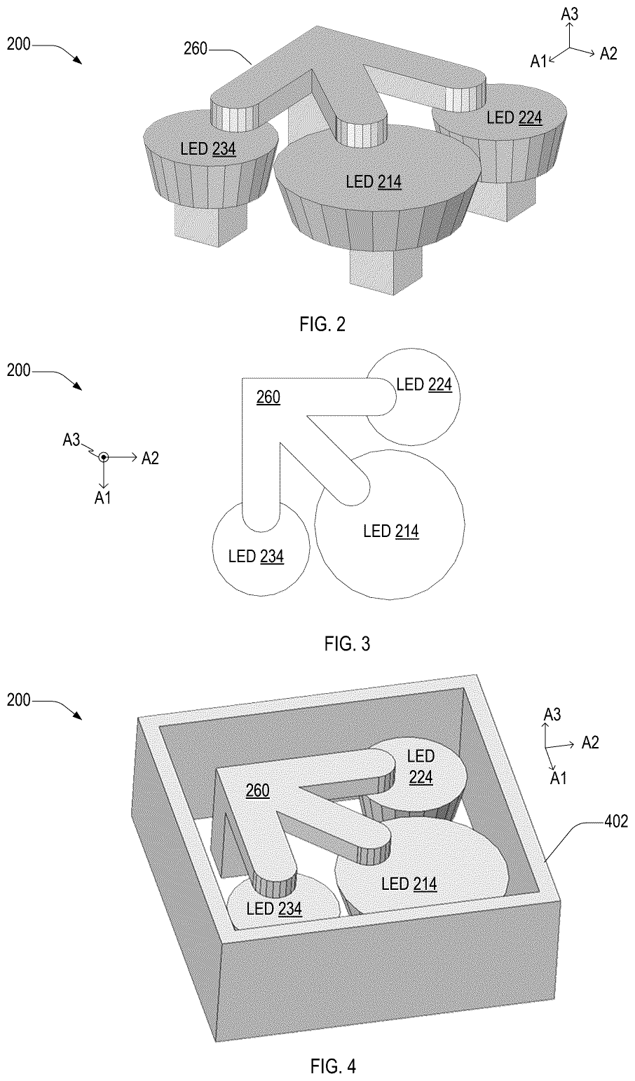

FIGS. 2-4 are respective schematics of a pixel 200, which is an example of pixel 100. Each pixel 200 includes an LED 214, an LED 224, an LED 234, and common-interconnection 260, which are respective examples of LED 114, LED 124, LED 134, and common-interconnection 160. LEDs 214, 224, and 234 may be coplanar in a horizontal plane. FIG. 3 is a plan view of pixel 200. FIG. 4 illustrates pixel 200 surrounded by an opaque isolation wall 402 for preventing optical cross-talk between pixel 200 and adjacent pixels 200, e.g., of LED array 100A. LEDs 214, 224, and 234 may have different cross-sectional areas in horizontal planes. In the example of FIG. 2, the cross-sectional area of LED 224 exceeds that of LED 234 and is smaller than that of LED 214.

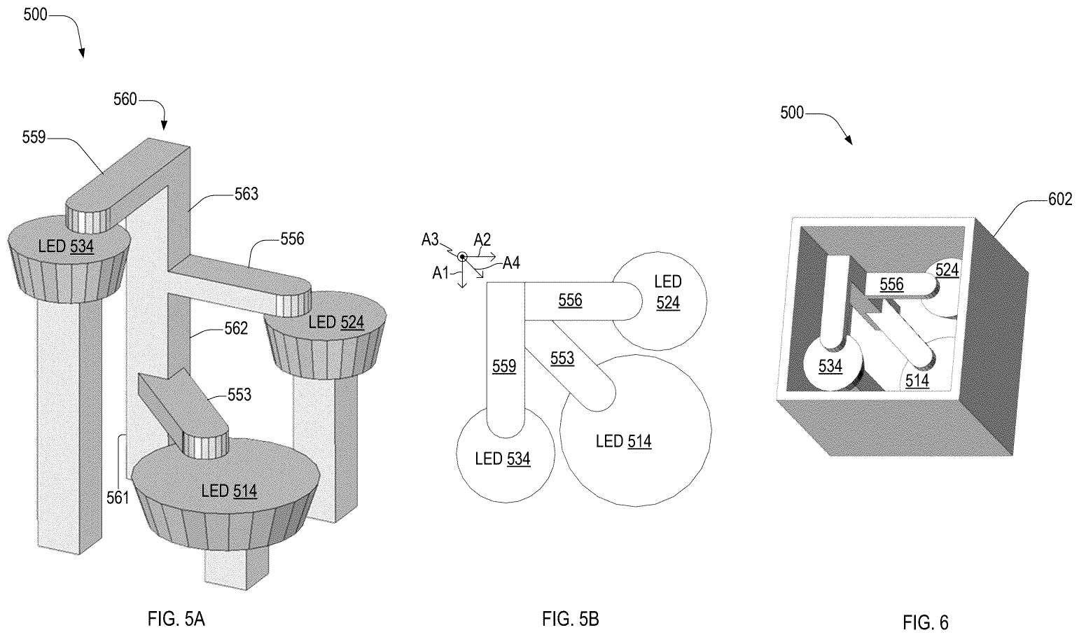

FIGS. 5A, 5B, and 6 are respective schematics of a pixel 500, which is an example of pixel 100. Each pixel 500 includes an LED 514, an LED 524, an LED 534, and common-interconnection 560, which are respective examples of LED 114, LED 124, LED 134, and common-interconnection 160. In embodiments, no two of LEDs 514, 524, and 534 of a same pixel 500 are coplanar in a horizontal plane. FIG. 6 illustrates pixel 500 surrounded by an opaque isolation wall 602 for preventing optical cross-talk between pixel 500 and adjacent pixels 500, e.g., of LED array 100A.

Common-interconnection 560 includes sections 561, 562, 563, which include lateral sections 553, 556, and 559, respectively. Parts of lateral sections 553, 556, and 559 may be in physical contact and/or electrical contact with LEDs 214, 224, and 234, respectively.

FIG. 5B denotes an axis A4, which is in the horizontal plane defined by axes A1 and A2, such that axis A4 is perpendicular to axis A3. A cross-sectional view of pixel 500 in a plane parallel to the A1-A3 plane includes a full length of lateral section 559 along axis A1. A cross-sectional view of pixel 500 in a plane parallel to the A2-A3 plane includes a full length of lateral section 556 along axis A2. A cross-sectional view of pixel 500 in a plane parallel to the A4-A3 plane includes a full length of lateral section 553 along axis A1.

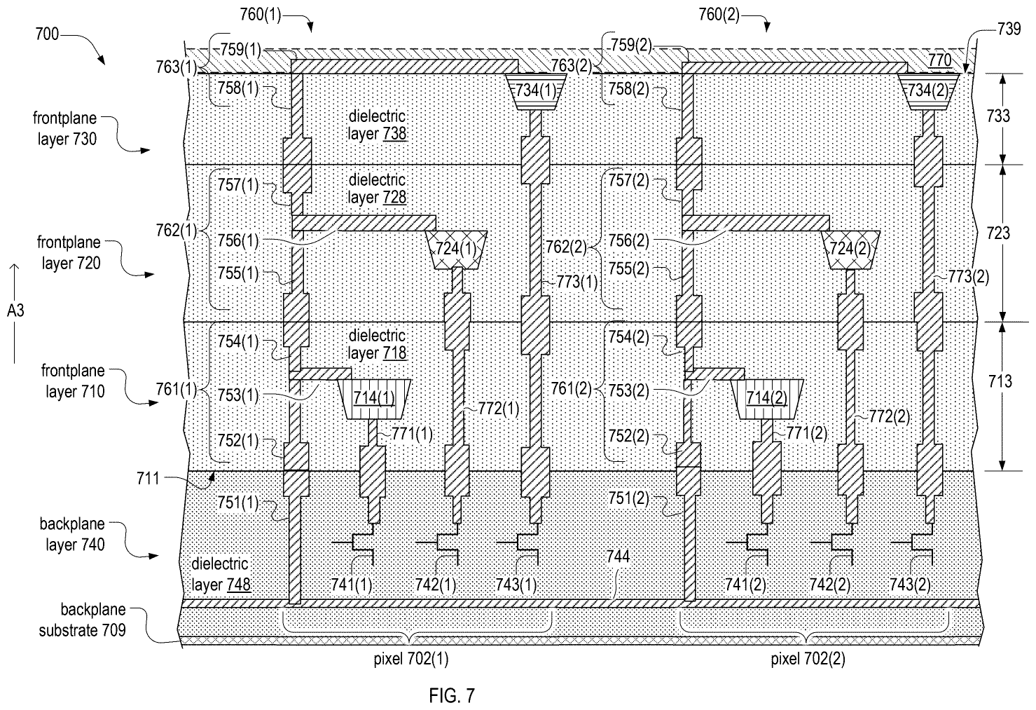

FIG. 7 is a connectivity diagram of a microLED display 700. MicroLED display 700 includes pixels 702(1) and 702(2). Herein, an element denoted by a reference number suffixed by a parenthetical number is an example of the element indicated by the reference number. For example, pixel 702(1) is an example (1) of pixel 702. Specific instances of an item may be referred to by use of a number in parentheses (e.g., pixel 702(1)) while numbers without parentheses refer to at least one of the enumerated items (e.g., pixel 702 or pixels 702).

Also herein, and unless specified otherwise, an element with a reference number suffixed by (1) is part of pixel 702(1), while an element suffixed by (2) is part of pixel 702(2). For example, pixel 702 includes an LED 714 and an LED 724, which means that pixel 702(1) includes LED 714(1) and LED 724(1), while pixel 702(2) includes LED 714(2) and LED 724(2).

Pixel 702 also includes LEDs 724 and common-interconnection 760. Each common-interconnection 760 is electrically connected to both a respective LED 714 and a respective LED 724. Pixel 702 may also include LEDs 734, in which case each common-interconnection 760 is electrically connected to a respective LED 734.

Pixel 500, LED 214, LED 224, and LED 234 are respective examples of pixel 702, LED 714, LED 724, and LED 734. When pixels 702 are instances of pixel 500, FIG. 7 does not illustrate a true cross-section of microLED display 700. Rather, FIG. 7 shows connectivity of components within and between layers of microLED display 700.

Pixel 702(1) may include a first opaque isolation wall 602 that surrounds pixel 702(1) while not surrounding pixel 702(2). Pixel 702(2) may include a second opaque isolation wall 602 that surrounds pixel 702(2) while not surrounding pixel 702(1). The first and the second opaque isolation walls may share a common side located between pixels 702(1) and 702(2).

MicroLED display 700 also includes a conductive element 744 electrically connected to each common-interconnection 760. In microLED display 700, conductive 744 may be opaque and may function as a ground plane or be a common voltage plane that is held at a common positive voltage or negative voltage. LEDs 714 and 724 are examples of LEDs 114 and 124, respectively. Each common-interconnection 760 is an example of common-interconnection 160.

MicroLED display 700 may include a transparent layer 770 covering each of pixels 702. Transparent layer 770 may be conductive transparent layer or a non-conductive transparent layer. When transparent layer 770 is conductive, it is electrically isolated from each of common-interconnection 760.

In embodiments, pixel 702 includes at least one of a driver circuit 741 electrically connected to LED 714, driver circuit 742 electrically connected to LED 724, and driver circuit 743 electrically connected to LED 734. MicroLED display 700 may include (i) a pixel-driver interconnection (PDI) 771 that electrically connects LED 714 to driver circuit 741, (ii) a PDI 772 that electrically connects LED 724 to driver circuit 742, and (iii) a PDI 773 that electrically connects LED 734 to driver circuit 743.

Driver circuit 741 and common-interconnection 760 may be electrically respectively connected to either (a) to an anode and a cathode of LED 714 or (b) to a first cathode and an anode of LED 714. Driver circuit 742 and common-interconnection 760 may be electrically respectively connected to either (a) to an anode and a cathode of LED 724 or (b) to a first cathode and an anode of LED 724. Driver circuit 743 and common-interconnection 760 may be electrically respectively connected to either (a) to an anode and a cathode of LED 734 or (b) to a first cathode and an anode of LED 734.

MicroLED display 700 may include a front-plane layer 710 and a back-plane layer 740. Front-plane layer 710 includes LED 714 and a segment 761 of common-interconnection 760. Back-plane layer 740 is bonded to front-plane layer 710 and includes driver circuit 741, bottom section 751 of common-interconnection 760, and bottom section 751 of common-interconnection 760. Back-plane layer 740 may be bonded to a planar surface 711 of front-plane layer 710. MicroLED display 700 may include a back-plane substrate 709, which supports back-plane layer 740.

In embodiments, microLED display 700 includes a front-plane layer 720 that includes LED 724 and a second segment 762 of common-interconnection 760. In such embodiments, back-plane layer 740 includes driver circuit 743. Front-plane layer 710 is between front-plane layer 720 and back-plane layer 740. MicroLED display 700 may also include a front-plane layer 730 that includes LEDs 734 and a third segment 763 of common-interconnection 760. Front-plane layer 720 is between front-plane layer 710 and front-plane layer 730.

Front-plane layers 710, 720, and 730 include respective dielectric layers 718, 728, and 738. Back-plane layer 740 includes a dielectric layer 748. Any two of dielectric layers 718, 728, 738, and 748 may have either identical material compositions or different material compositions. Herein, when a component of a microLED display 700 is said to be part of a front-plane layer 710, 720, or 730, said component may be partially or completely embedded in dielectric layer that of the front-plane layer. For example: each LED 714 and each segment 761 may be at least partially embedded in dielectric layer 718; each LED 724 and each segment 762 may be at least partially embedded in dielectric layer 728; and each LED 734 and each segment 763 may be at least partially embedded in dielectric layer 738. Similarly, each bottom section 751 and each of driver circuits 741-743 may be at least partially embedded in dielectric layer 748. In the example of FIG. 7, conductive element 744 is embedded in back-plane layer 740. Without departing from the scope of the embodiments presented herein, conductive element 744 may be embedded in any of front-plane layers 718, 728, or 738.

Embodiments of microLED display 700 include a (i) conductive lateral section 753 extending between, and electrically connecting, common-interconnection 760 to 714 and (ii) a conductive lateral section 756 extending between, and electrically connecting, common-interconnection 760 to LED 724. The following description applies to such embodiments. Segment 761 of common-interconnection 760 includes a first vertical subsegment extending through front-plane layer 710 and lateral section 753 that extends from the first vertical subsegment to the LED 714. The first vertical subsegment includes vertical subsegments 752 and 754. Segment 762 of common-interconnection 760 includes a second vertical subsegment extending through front-plane layer 720 and lateral section 756 that extends from the third vertical subsegment to LED 724. The second vertical subsegment includes vertical subsegments 755 and 757. When microLED display 700 includes LEDs 734, segment 763 of common-interconnection 760 includes a vertical subsegment 758 extending through front-plane layer 730 and a lateral section 759 that extends from vertical subsegment 758 to LED 734. Lateral section 759 electrically connects LED 734 to common-interconnection 760.

In embodiments, display 190 includes a plurality of pixel pairs. Each pixel pair of the plurality of pixel pairs includes one pixel 702(1) and one pixel 702(2), such that the plurality of pixel pairs includes a plurality of common-interconnections 760(1) and a plurality of common-interconnections 760(2). In embodiments, each of the plurality of common-interconnections 760(1) is electrically isolated from (i) each other common-interconnection 760(1) of the plurality of common-interconnections 760(1) and (ii) each second common-interconnection 760(2) of the plurality of common-interconnection 760(2). In other embodiments, each common-interconnection 760 is electrically connected to conductive element 744.

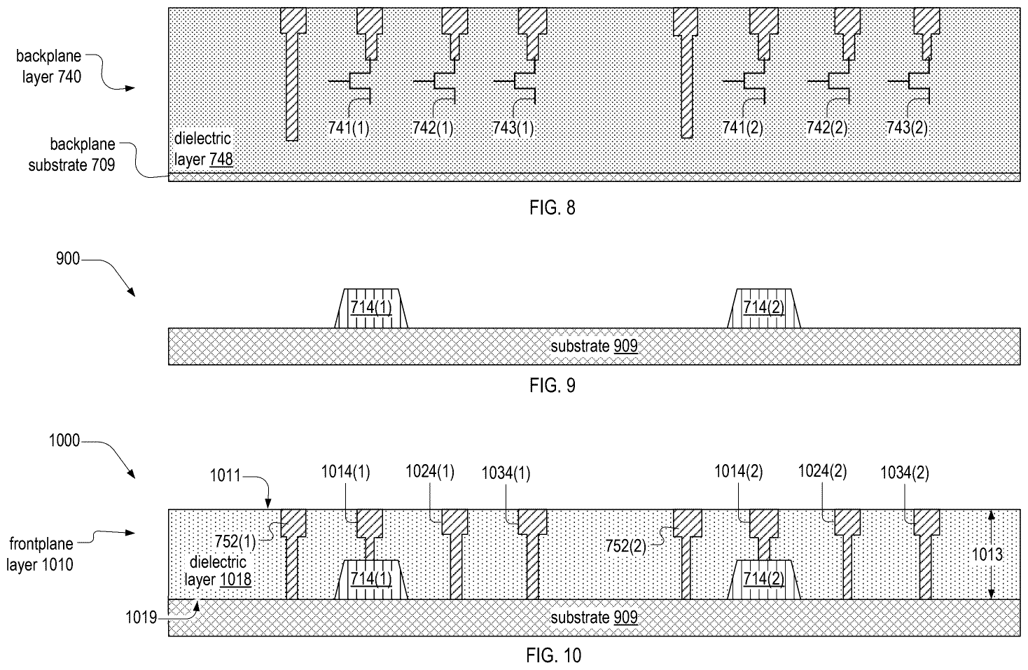

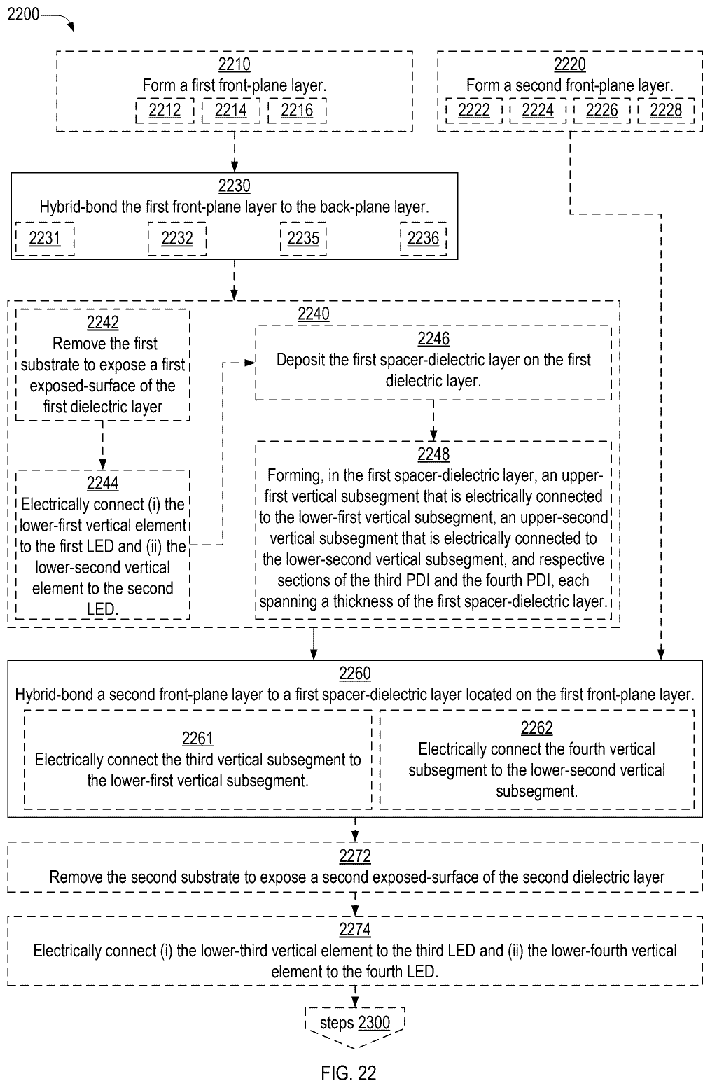

FIGS. 8-21 depict parts results of fabrication steps of a method for fabricating microLED display 700. FIG. 22 is a flowchart illustrating a method 2200, which is an example of such a method.

FIG. 8 shows back-plane layer 740 on back-plane substrate 709. FIG. 9 illustrates an intermediate structure 900, which includes LEDs 714 on a substrate 909. FIG. 10 depicts an intermediate structure 1000, which includes a front-plane layer 1010 on intermediate structure 900. Front-plane layer 1010 includes a dielectric layer 1018, and lower-first vertical subsegment 752 each spanning a thickness 1013 of dielectric layer 1018. Front-plane layer 1010 also includes PDI sections 1014, 1024, and 1034 partially embedded in dielectric layer 1018. PDI sections 1014, 1024, and 1034 are respective sections of PDIs 771, 772, and 773. Dielectric layer 1018 has a surface 1019 proximate substrate 909 and a surface 1011 opposite surface 1019.

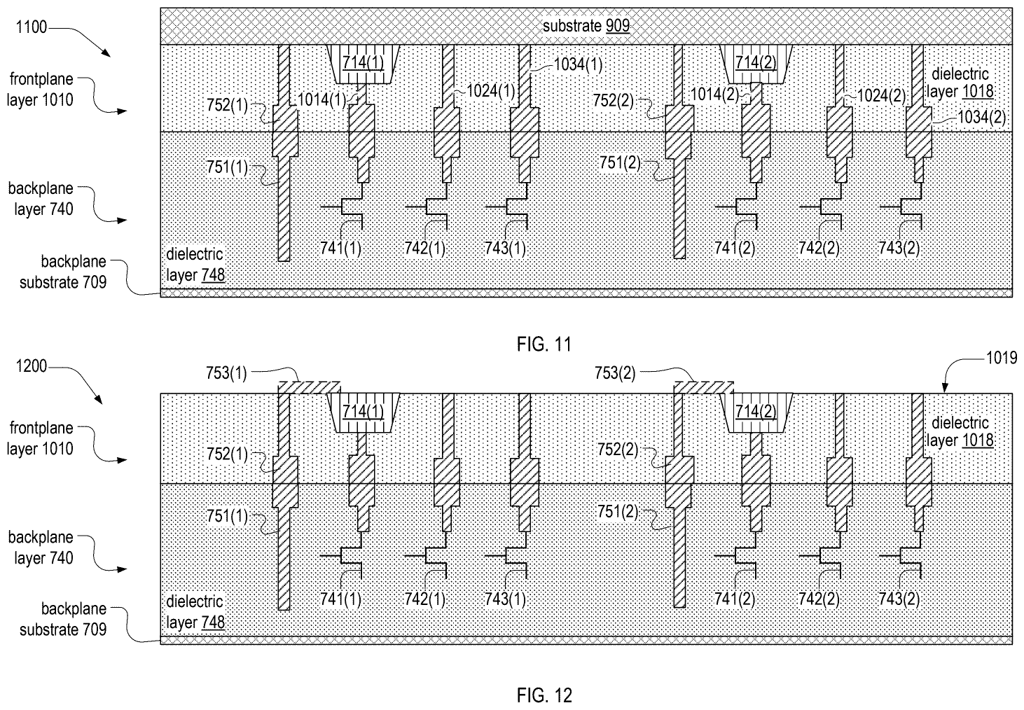

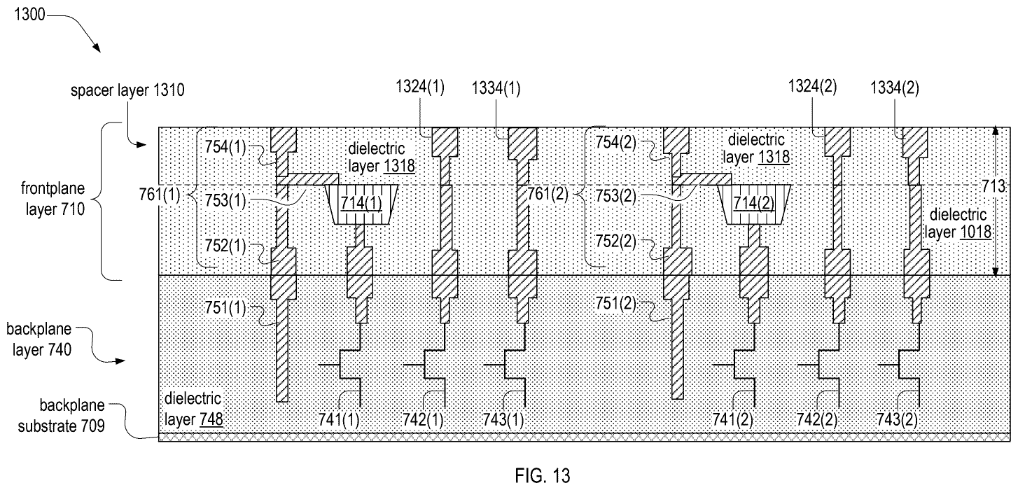

FIG. 11 depicts an intermediate structure 1100, which is intermediate structure 1000 on back-plane layer 740. FIG. 12 depicts an intermediate structure 1200, which intermediate structure 1100 after removal of substrate 909. FIG. 12 illustrates conductive lateral sections 753 on intermediate structure 1200, as embodiments of a method for fabricating microLED display 700 including depositing sections 753 on surface 1019. FIG. 13 depicts an intermediate structure 1300, which is intermediate structure 1200 with the addition of a spacer layer 1310 on dielectric layer 1018 to yield front plane layer 710.

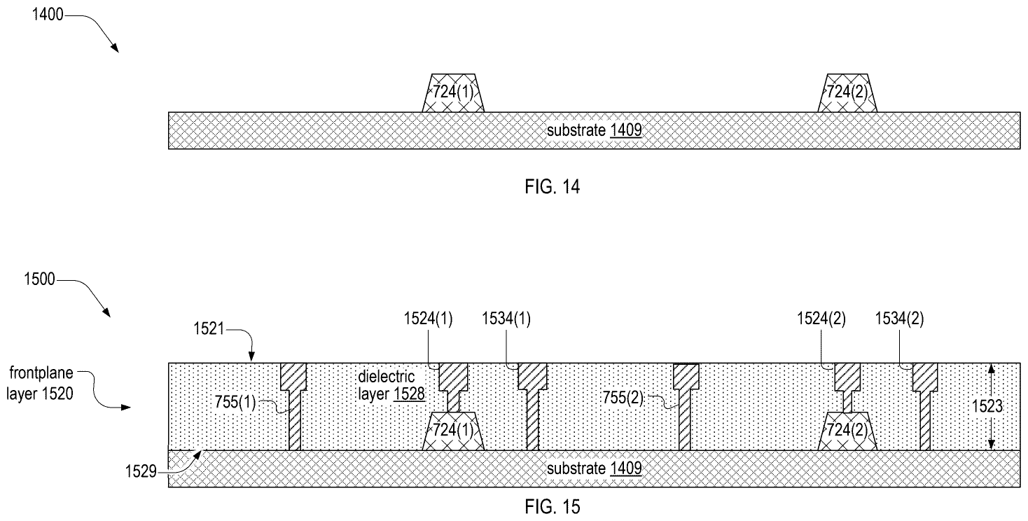

FIG. 14 depicts an intermediate structure 1400, which includes LEDs 724 on a substrate 1409. FIG. 15 depicts an intermediate structure 1500, which includes a front-plane layer 1520 on intermediate structure 1400. Front-plane layer 1520 includes a dielectric layer 1528, and vertical subsegments 755 each spanning a thickness 1523 of dielectric layer 1528. Front-plane layer 1520 also includes PDI sections 1524, each of is a section of a respective PDI 772. LEDs 724 are embedded in dielectric layer 1528. In embodiments, front-plane layer 1520 is part of front-plane layer 720. Dielectric layer 1258 has a surface 1529 proximate substrate 1409 and a surface 1511 opposite surface 1529.

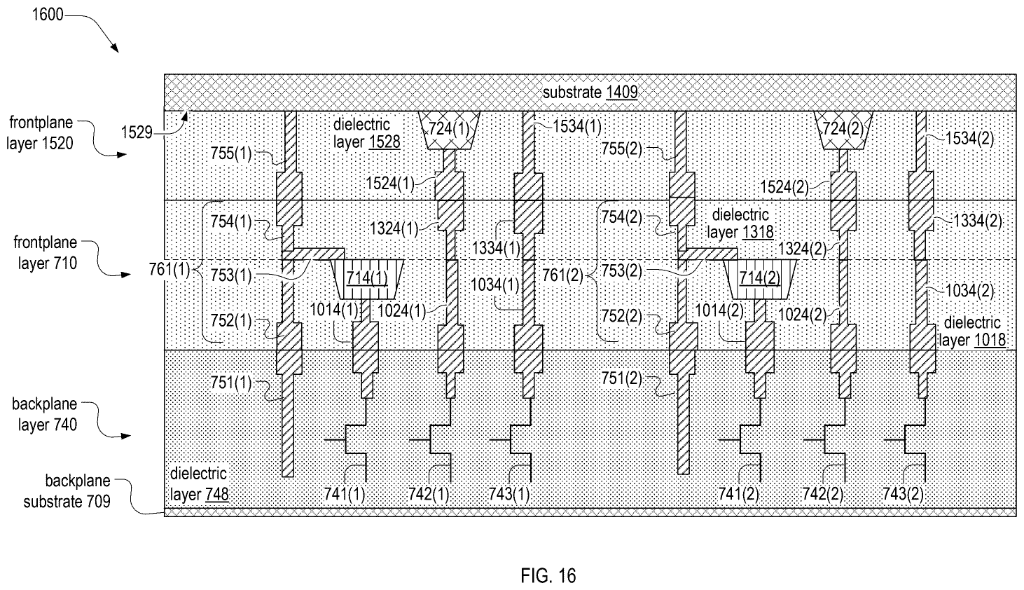

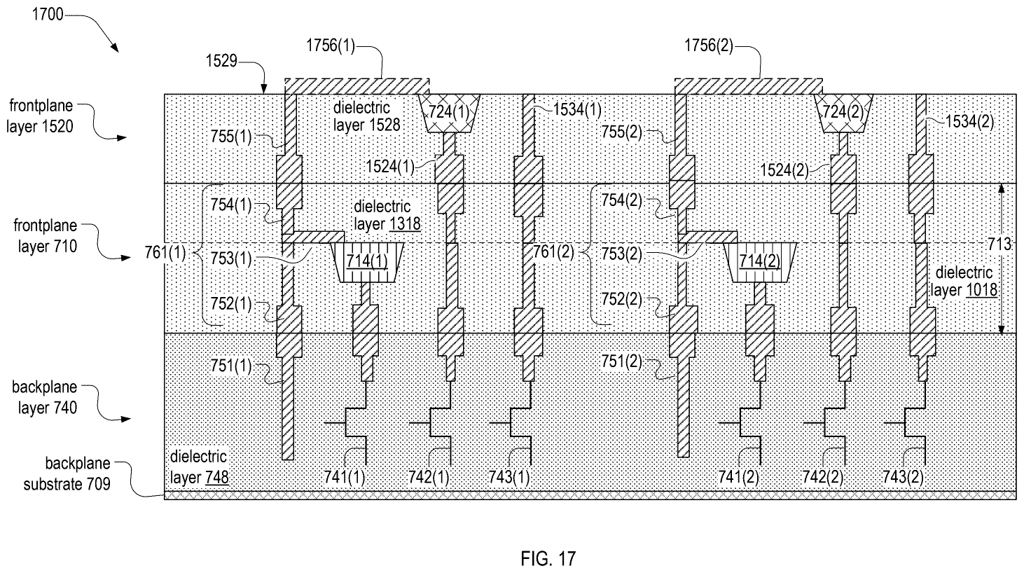

FIG. 16 depicts an intermediate structure 1600, which is intermediate structure 1300 with intermediate structure 1500 thereon. FIG. 17 depicts an intermediate structure 1700, which intermediate structure 1600 after removal of substrate 1409. FIG. 17 illustrates conductive lateral sections 756 on intermediate structure 1700, as embodiments of a method for fabricating microLED display 700 including depositing sections 756 on surface 1519.

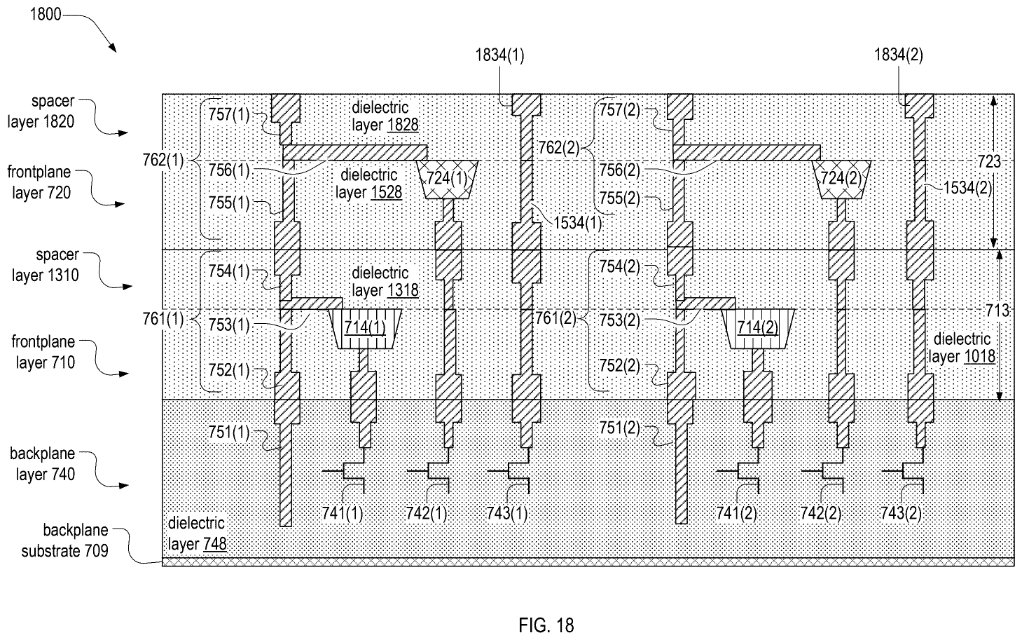

FIG. 18 depicts an intermediate structure 1800, which is intermediate structure 1700 with the addition of a spacer layer 1820 thereon. Spacer layer 1820 includes a dielectric layer 1828, conductive lateral sections 756, vertical subsegments 757, and sections 1834 of PDIs 773. In embodiments, spacer layer 1820 is part of front-plane layer 720, and dielectric layer 1828 is part of dielectric layer 728.

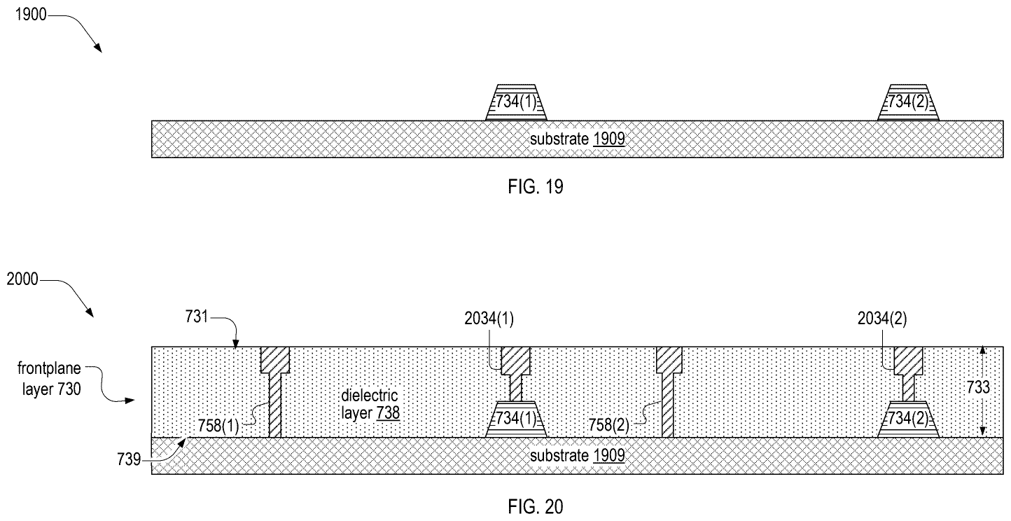

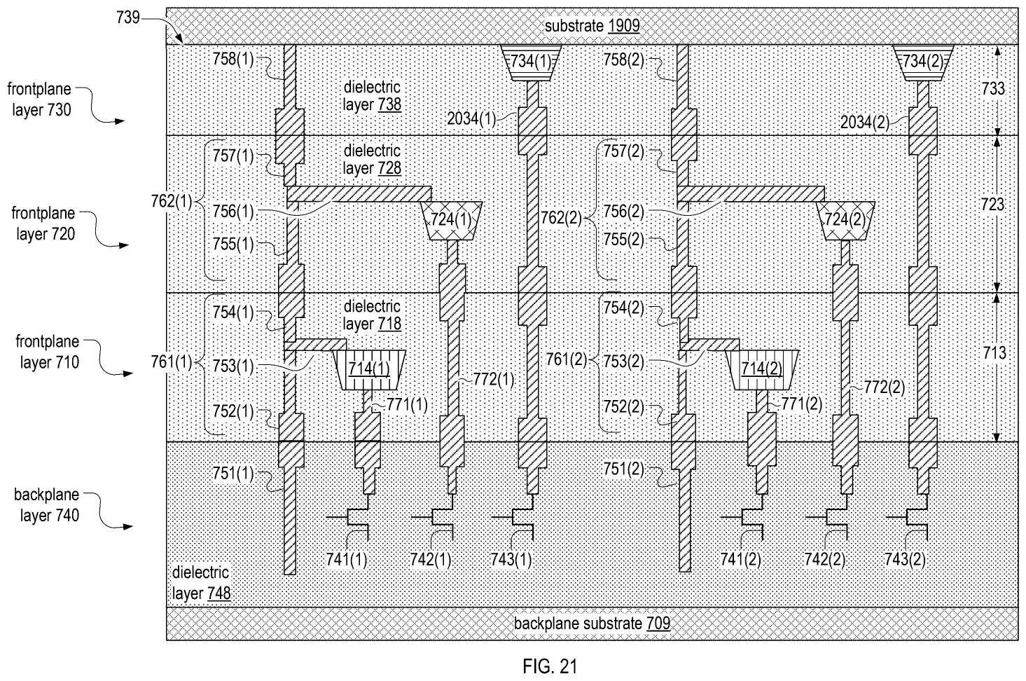

FIG. 19 depicts an intermediate structure 1900, which includes LEDs 734 on a substrate 1909. FIG. 20 depicts an intermediate structure 2000, which includes front-plane layer 730 on substrate 1909. Front-plane layer 730 includes a dielectric layer 738, and vertical subsegments 758 each spanning a thickness 733 of dielectric layer 738. Front-plane layer 730 also includes PDI sections 2034, each of is a section of a respective PDI 773. LEDs 734 are embedded in dielectric layer 738. Dielectric layer 738 has a surface 739 proximate substrate 1909 and a surface 731 opposite surface 739. FIG. 21 depicts an intermediate structure 2100, which is intermediate structure 1800 with intermediate structure 2000 thereon.

FIG. 22 is a flowchart illustrating a method 2200 for fabricating a LED pixel-pair. The pixel-pair may include, or consist of, pixels 702(1) and 702(2) described in FIG. 7. FIG. 8-21 include intermediate structures resulting from steps of method 2200. FIGS. 8-21 and FIG. 22 are best viewed together in the following description. Method 2200 includes at least one of steps 2230, 2240, and 2260.

The following description of method 2200 includes parenthetical numbers following term used in a method step. The parenthetical number indicates that the element associated with the number in parenthesis is an example of the term. For example, the description of step 2230 below recites “a first front-plane layer (1010),” which means that front-plane layer 1010 of FIG. 10 is an example of the first front-plane layer introduced in step 2230.

Step 2230 includes hybrid-bonding a first front-plane layer (1010) to a back-plane layer (740). The first front-plane layer includes (i) a first dielectric layer (1018), (ii) a first LED (714(1)) and a second LED (714(2)) embedded in the first dielectric layer, (iii) a lower-first vertical subsegment (752(1)) and lower-second vertical subsegment (752(2)) each spanning a thickness of the first dielectric layer. In embodiments, step 2230 results in intermediate structure 1100, FIG. 11.

Step 2230 may include at least one of steps 2231, 2232, 2235, and 2236. Step 2231 includes electrically connecting the lower-first vertical subsegment (752(1)) to a first back-plane interconnection segment (751(1)) of the back-plane layer (740).

Step 2232 includes electrically connecting the lower-second vertical subsegment (752(2)) to a second back-plane interconnection segment (751(2)), of the back-plane layer (740). The second back-plane interconnection segment (751(2)) is electrically isolated from the lower-first vertical subsegment (752(1)).

Step 2235 includes electrically connecting the first LED (714(1)) to a first driver circuit (741(1)) of the back-plane layer (740). Step 2236 includes electrically connecting the second LED (714(2)) to a second driver circuit (741(2)) of the back-plane layer (740). In embodiments, the first front-plane layer (1010) includes first driver-circuit segments (1014(1,2)) electrically connected to the first and second LEDs (714(1,2)) respectively and spanning between either (i) the first LED or the second LED and (ii) a first dielectric-surface (1011) of the first dielectric layer (1018) proximate the back-plane layer (740). In such embodiments, step 2235 includes electrically connecting the first driver-circuit segment (1014(1)) to the first driver circuit (741(1)). Also in such embodiments, step 2236 includes electrically connecting the second driver-circuit segment (1014(2)) to the second driver circuit (741(2)).

Method 2200 may include a step 2240 after step 2230. Step 2240 includes at least of steps 2242 and 2244. In embodiments, steps 2242 and 2244 result in intermediate structure 1200, FIG. 12.

Step 2242 includes removing the first substrate (909) to expose a surface (1019) of the first dielectric layer (1018). Step 2244 includes electrically connecting (i) the lower-first vertical subsegment (752(1)) to the first LED (714(1)) and (ii) the lower-second vertical subsegment (752(2)) to the second LED (714(2)) by depositing respective conductive elements (753(1,2)) on the surface (1019), as shown in FIG. 12.

Step 2240 may also include at least one of steps 2246 and 2248. In embodiments, steps 2246 and 2248 result in intermediate structure 1300, FIG. 13. Step 2246 includes depositing the first spacer-dielectric layer (1318) on the first dielectric layer (1018). Step 2248 includes forming, in the first spacer-dielectric layer (1318), an upper-first vertical subsegment (754(1)) that is electrically connected to the lower-first vertical subsegment (752(1)), an upper-second vertical subsegment (754(2)) that is electrically connected to the lower-second vertical subsegment (752(2)), and respective sections of the third PDI and the fourth PDI (1324(1,2), 1334(1,2)) each spanning a thickness of the first spacer-dielectric layer (1318).

Step 2260 includes hybrid-bonding a second front-plane layer (1520) to a first spacer-dielectric layer (1318) located on the first front-plane layer (710). In embodiments, step 2260 results in intermediate structure 1600, FIG. 16. The second front-plane layer includes (i) a second dielectric layer (1528), (ii) a third LED (724(1)) and a fourth LED (724(2)) embedded in the second dielectric layer and (iii) a third common-interconnection segment (762(1)) and fourth common-interconnection segment (762(2)) each spanning a thickness (723) of the second dielectric layer. Step 2260 may include adjoining the second front-plane layer (1520) and the first spacer-dielectric layer (1318).

Step 2260 may include at least one of steps 2261 and 2262. Step 2261 includes electrically connecting the lower-third vertical subsegment (755(1)) to the first common-interconnection segment (761(1)), which includes vertical subsegment 752(1). Step 2262 includes electrically connecting the lower-fourth vertical subsegment (755(2)) to the second common-interconnection segment (761(2)), vertical subsegment 752(2).

In embodiments, the first, the second, the third, and the fourth LED are electrically connected, respectively, to a first, a second, a third, and a fourth driver circuit of the back-plane layer via a respective first, a second, a third, and a fourth pixel-driver interconnection (PDI). PDIs 771 are examples the first and second PDIs. PDIs 772 are examples of the third and fourth PDIs. In such embodiments, method 2200 may include a step 2210 of forming the first front-plane layer (710).

Step 2210 includes steps 2212, 2214, and 2216. Step 2212 includes forming the first LED (714(1)) and the second LED (714(2)) on a first substrate (909). In embodiments, step 2212 results in intermediate structure 900, FIG. 9. Step 2214 includes depositing the first dielectric layer (1018) on the first substrate.

Step 2216 includes forming, in the first dielectric layer (1018), a lower-first vertical subsegment (752(1)), a lower-second vertical subsegment (752(2)), and respective sections of the first PDI (1014(1)), the second PDI (1014(2)), the third PDI (1024(1)), and the fourth PDI (1024(2)) each spanning a thickness (1013) of the first dielectric layer (1018). In embodiments, step 2216 results in intermediate structure 1000, FIG. 10.

In embodiments, the third and the fourth LED are electrically connected, respectively, to a third and a fourth driver circuit of the back-plane layer via a respective third and fourth pixel-driver interconnection. LEDs 724 are examples of the third LED and fourth LED. PDIs 772 are examples of the third and fourth pixel-driver interconnections. In such embodiments, method 2200 may include step 2220 of forming the second front-plane layer, an example of which is front-plane layer 720.

Step 2220 includes steps 2222, 2224, and 2226. Step 2222 includes forming the third LED (724(1)) and the fourth LED (724(2)) on a second substrate (1409). In embodiments, step 2222 results in intermediate structure 1400, FIG. 14. Step 2224 includes depositing the second dielectric layer (1528) on the second substrate.

Step 2226 includes forming, in the second dielectric layer, a lower-third vertical subsegment (755(1)), a lower-fourth vertical subsegment (755(2)), and respective sections of the third PDI and the fourth PDI (1524(1,2)) each spanning a thickness of the second dielectric layer. In embodiments, step 2226 results in intermediate structure 1500, FIG. 15.

Method 2200 may include step 2272, which is executed after step 2260. Step 2272 includes removing the second substrate (1409) to expose a surface (1529) of the second dielectric layer (1528). In embodiments, step 2272 results in intermediate structure 1700, FIG. 17. When method 2200 includes step 2272, it may also include step 2274. Step 2274 includes electrically connecting (i) the lower-third vertical subsegment (755(1)) to the third LED and (ii) the lower-fourth vertical subsegment (755(2)) to the fourth LED by depositing respective conductive elements (756(1,2)) on the surface (1529), as shown in FIG. 17. Step 2274 results in intermediate structure 1800, FIG. 18, without dielectric layer 1828, vertical subsegments 757, and sections 1834.

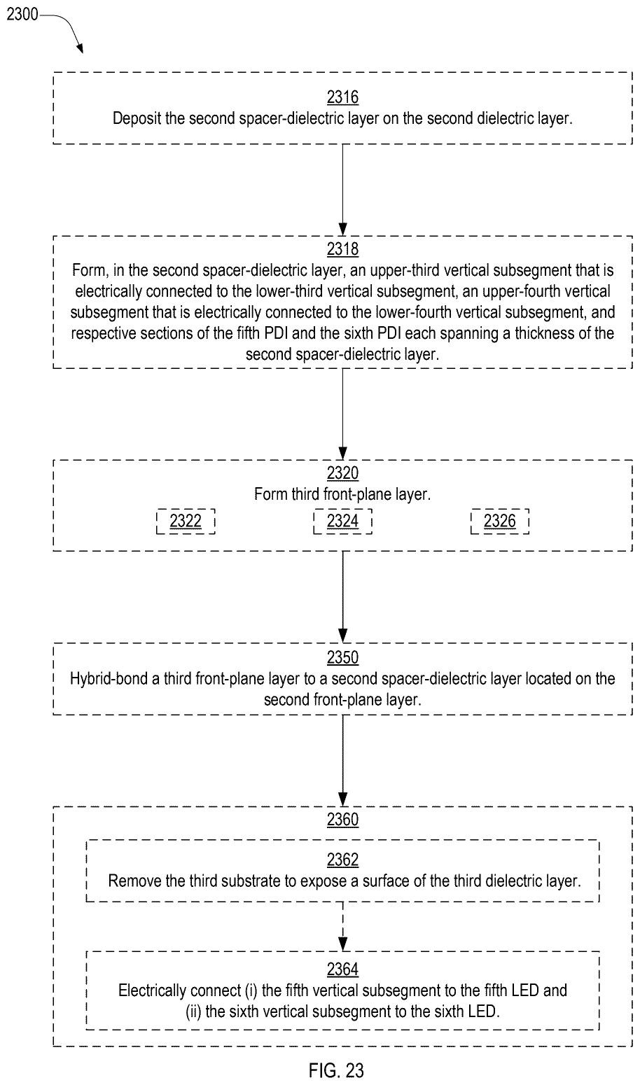

Method 2200 may include additional steps 2300 shown in FIG. 23. Steps 2300 includes at least one of steps 2316, 2318, 2320, 2350, and 2360.

Step 2316 includes depositing the second spacer-dielectric layer (1828) on the second dielectric layer (1528). Step 2318 includes forming, in the second spacer-dielectric layer (1828), an upper-third vertical subsegment (757(1)) that is electrically connected to the lower-third vertical subsegment (755(1)), an upper-fourth vertical subsegment (757(2)) that is electrically connected to the lower-third vertical subsegment (755(2)), and respective sections (1834(1,2)) of the fifth PDI and the sixth PDI each spanning a thickness of the second spacer-dielectric layer (1828). In embodiments, steps 2316 and 2318 result in intermediate structure 1800, FIG. 18.

In embodiments, the fifth LED and the sixth LED are electrically connected, respectively, to a fifth and a sixth driver circuit of the back-plane layer via a respective fifth and a sixth PDI (773(1,2)) In such embodiments, steps 2300 may include a step 2320 of forming the third front-plane layer (730). Step 2320 includes at least one of steps 2322, 2324, and 2326. Step 2322 includes forming the fifth LED (734(1)) and the sixth LED (734(2)) on a third substrate (1909). In embodiments, step 2322 results in intermediate structure 1900, FIG. 19.

Step 2324 includes depositing the third dielectric layer (738) on the third substrate. Step 2326 includes forming, in the third dielectric layer, the fifth vertical subsegment (758(1)), the sixth vertical subsegment (758(2)), and respective sections (2034(1,2)) of the fifth PDI and the sixth PDI each spanning a thickness of the third dielectric layer. In embodiments, steps 2324 and 2326 result in intermediate structure 2000, FIG. 20.

Step 2350 includes hybrid-bonding a third front-plane layer (730) to a second spacer-dielectric layer (1828) located on the second front-plane layer (720). The third front-plane layer includes (i) a third dielectric layer (738), (ii) a fifth LED (734(1)) and a sixth LED (734(2)) embedded in the third dielectric layer and (iii) a fifth vertical subsegment (758(1)) and a sixth vertical subsegment (758(2)) each spanning a thickness (733) of the third dielectric layer. In step 2350, hybrid-bonding the third front-plane layer includes: electrically connecting the fifth vertical subsegment (758(1)) to the lower-third vertical subsegment 755(1). The hybrid bonding of step 2350 also includes electrically connecting the sixth vertical subsegment (758(2)) to the lower-fourth vertical subsegment 755(2).

In embodiments, the third, the fourth, the fifth, and the sixth LED are electrically connected, respectively, to a third, a fourth, a fifth, and a sixth driver circuit of the back-plane layer via a respective third, a fourth, a fifth, and a sixth pixel-driver interconnection (PDI) (772(1,2), 773(1,2)). In such embodiments, forming the second front-plane layer of step 2220 may include a step 2228. Step 2228 includes forming, in the second dielectric layer (1528), a lower-fifth vertical subsegment (1534(1)) and a lower-sixth vertical subsegment (1534(2)). Respective sections (1534(1,2)) of the fifth PDI (773(1)) and the sixth PDI (773(2)) each span a thickness of the second dielectric layer. In embodiments, step 2228 results in intermediate structure 1500, FIG. 15.

Step 2360 follows step 2350 and includes 2362 and 2364, which are similar to steps 2242 and 2244, respectively. Step 2362 includes removing the third substrate (1909) to expose a surface (739) of the third dielectric layer (738). Step 2364 includes electrically connecting (i) the fifth vertical subsegment (758(1)) to the fifth LED (734(1)) and (ii) the sixth vertical subsegment (758(2)) to the sixth LED (734(1)) by depositing respective conductive elements (759(1,2)) on the surface (739). FIG. 7 illustrates lateral sections 759 on surface 739.

### Combinations of Features

Features described above, as well as those claimed below, may be combined in various ways without departing from the scope hereof. The following enumerated examples illustrate some possible, non-limiting combinations.

Embodiment 1. A micro light-emitting diode (LED) display (700) comprising: a first pixel including a first LED (714(1)), a third LED (724(1)), and a first common-interconnection (760(1)) electrically connected to each of the first LED and the third LED; a second pixel including a second LED (714(2)), a fourth LED (724(2)), and a second common-interconnection (760(2)) electrically connected to each of the second LED and the fourth LED; and an opaque conductive element (744) electrically connected to each of the first common-interconnection and the second common-interconnection.

Embodiment 2. The LED display of Embodiment 1, further comprising a non-conductive transparent layer (770) covering each of the first pixel and the second pixel.

Embodiment 3. The LED display of Embodiment 1, further comprising a conductive transparent layer covering each of the first pixel and the second pixel and being electrically isolated from each of the first common-interconnection and the second common-interconnection.

Embodiment 4. The LED display of Embodiment 1, the opaque conductive element being a ground plane or a common voltage plane.

Embodiment 5. The LED display of Embodiment 1, the first pixel further including a first driver circuit (741(1)) electrically connected to the first LED, the second pixel further including a second driver circuit (741(2)) electrically connected to the second LED, and further comprising: a front-plane layer (710) that includes the first LED, the second LED, a first segment (761(1)) of the first common-interconnection (760(1)), and a first segment (761(2)) of the second common-interconnection (760(2)); and a back-plane layer (740) bonded to the front-plane layer and including the first driver circuit and the second driver circuit, a bottom section (751(1)) of the first common-interconnection, and a bottom section (751(2)) of the second common-interconnection.

Embodiment 6. The LED display of Embodiment 5, the first pixel further including a third driver circuit (742(1)) electrically connected to the third LED, the second pixel further including a fourth driver circuit (742(2)) electrically connected to the fourth LED, and further comprising: a second front-plane layer (720) that includes the third LED, the fourth LED, a second segment (762(1)) of the first common-interconnection, and a second segment (762(2)) of the second common-interconnection; and the back-plane layer (740) further including the third driver circuit and the fourth driver circuit, the first front-plane layer being between the second front-plane layer and the back-plane layer.

Embodiment 7. (add horizontal extensions to LEDs 1-4) The LED display of Embodiment 6, the first segment (761(1)) of the first common-interconnection (760(1)) including a first vertical subsegment (752(1))/754(1)) extending through the first front-plane layer and a first lateral section (753(1)) that extends from the first vertical subsegment to the first LED; the second segment (762(1)) of the first common-interconnection (760(1)) including a third vertical subsegment (755(1))/757(1)) extending through the second front-plane layer and a third horizontal (756(1)) section that extends from the third vertical subsegment to the third LED; the first segment (761(2)) of the second common-interconnection (760(2)) including a second vertical subsegment (752(2))/754(2)) extending through the first front-plane layer and a second lateral section (753(2)) that extends from the second vertical subsegment to the second LED; and the second segment (762(1)) of the second common-interconnection (760(2)) including a fourth vertical subsegment (755(2))/757(2)) extending through the second front-plane layer and a fourth lateral section (756(2)) that extends from the fourth vertical subsegment to the fourth LED.

Embodiment 8. The LED display of Embodiment 1, the first pixel further including a fifth LED (734(1)) electrically connected to the first common-interconnection, the second pixel further including a sixth LED (734(2)) electrically connected to the second common-interconnection, and further comprising: a third front-plane layer that includes the fifth LED, the sixth LED, a third segment of the first common-interconnection, and a third segment of the second common-interconnection, the second front-plane layer being between the third front-plane layer and the first front-plane layer.

Embodiment 9. The LED display of Embodiment 8, the first segment (761(1)) of the first common-interconnection including a first vertical subsegment (752(1)) extending through the first front-plane layer and a first lateral section (753(1)) that extends from the first vertical subsegment to the first LED; the second segment of the first common-interconnection including a third vertical subsegment (755(1), 1657(1)) extending through the second front-plane layer and a third lateral section (756(1)) that extends from the third vertical subsegment to the third LED; the third segment (763(1)) of the first common-interconnection including a fifth vertical subsegment (758(1)) extending through the third front-plane layer and a fifth lateral section (759(1)) that extends from the fifth vertical subsegment to the fifth LED; the first segment of the second common-interconnection including a second vertical subsegment extending through the first front-plane layer and a second lateral section that extends from the second vertical subsegment to the second LED; the second segment of the second common-interconnection including a fourth vertical subsegment extending through the second front-plane layer and a fourth lateral section that extends from the fourth vertical subsegment to the fourth LED; and the third segment (763(2)) of the second common-interconnection including a sixth vertical subsegment (758(2)) extending through the third front-plane layer and a sixth lateral section that extends from the sixth vertical subsegment to the sixth LED.

Embodiment 10. A LED display comprising: a plurality of pixel pairs, each pixel pair of the plurality of pixel pairs including the first pixel of Embodiment 1 and the second pixel of Embodiment 1, such that the plurality of pixel pairs includes a plurality of first common-interconnections and a plurality of second common-interconnections; each of the plurality of first common-interconnections being electrically isolated from (i) each other first common-interconnections of the plurality of first common-interconnections and (ii) each second common-interconnection of the plurality of second common-interconnections.

Embodiment 11. A method for fabricating an LED pixel-pair, comprising: hybrid-bonding a first front-plane layer (1010) to a back-plane layer (740), the first front-plane layer including (i) a first dielectric layer (1018), (ii) a first LED (714(1)) and a second LED (714(2)) embedded in the first dielectric layer, (iii) a lower-first vertical subsegment (752(1)) and a lower-second vertical subsegment (752(2)) each spanning a thickness (713) of the first dielectric layer; and (2260) hybrid-bonding a second front-plane layer (1520) to a first spacer-dielectric layer (1318) located on the first front-plane layer (710), the second front-plane layer including (i) a second dielectric layer (1528), (ii) a third LED (724(1)) and a fourth LED (724(2)) embedded in the second dielectric layer and (iii) a third vertical subsegment (755(1)) and fourth vertical subsegment (755(2)) each spanning a thickness (1523) of the second dielectric layer.

Embodiment 12. The method of Embodiment 11, hybrid-bonding the first front-plane layer to the back-plane layer comprising: (2231) electrically connecting the lower-first vertical subsegment (752(1)) to a first back-plane interconnection segment of the back-plane layer; and (2232) electrically connecting the lower-second vertical subsegment (752(2)) to a second back-plane interconnection segment, of the back-plane layer, that is electrically isolated from the lower-first vertical subsegment (752(1)).

Embodiment 13. The method of Embodiment 11, hybrid-bonding the first front-plane layer to the back-plane layer further comprising: (2235) electrically connecting the first LED (714(1)) to a first driver circuit (741(1)) of the back-plane layer; and (2236) electrically connecting the second LED (714(2)) to a second driver circuit (741(2)) of the back-plane layer.

Embodiment 14. The method of Embodiment 11, hybrid-bonding the second front-plane layer to the first spacer-dielectric layer comprising: (2261) electrically connecting the third vertical subsegment (755(1)) to the lower-first vertical subsegment (752(1)); and (2262) electrically connecting the fourth vertical subsegment (755(2)) to the lower-second vertical subsegment (752(2)).

Embodiment 15. The method of Embodiment 11, the first, the second, the third, and the fourth LED being electrically connected, respectively, to a first, a second, a third, and a fourth driver circuit of the back-plane layer via a respective first, a second, a third, and a fourth pixel-driver interconnection (PDI) (771, 772), and further comprising forming the first front-plane layer (710) by: (2212) forming the first LED and the second LED on a first substrate (909); (2214) depositing the first dielectric layer (1018) on the first substrate; and (2216) forming, in the first dielectric layer, a lower-first vertical subsegment (752(1)), a lower-second vertical subsegment (752(2)), and respective sections of the first PDI, the second PDI, the third PDI, and the fourth PDI (1014(1,2), 1024(1,2)) each spanning a thickness of the first dielectric layer.

Embodiment 16. The method of Embodiment 15, further comprising, after hybrid-bonding (2230, step 4) the first front-plane layer (1010) to the back-plane layer (740): (2242) removing the first substrate (909) to expose a surface of the first dielectric layer; and (2244) electrically connecting (i) the lower-first vertical subsegment (752(1)) to the first LED and (ii) the lower-second vertical subsegment (752(2)) to the second LED by depositing respective conductive elements (753(1,2)) on the surface.

Embodiment 17. The method of Embodiment 16, further comprising: (2246) depositing the first spacer-dielectric layer (1318) on the first dielectric layer (1018); (2248) forming, in the first spacer-dielectric layer (1318), an upper-first vertical subsegment (754(1)) that is electrically connected to the lower-first vertical subsegment (752(1)), an upper-second vertical subsegment (754(2)) that is electrically connected to the lower-second vertical subsegment (752(2)), and respective sections of the third PDI and the fourth PDI (1324(1,2), 1334(1,2)) each spanning a thickness of the first spacer-dielectric layer (1318).

Embodiment 18. The method of Embodiment 11, the third and the fourth LED being electrically connected, respectively, to a third and a fourth driver circuit of the back-plane layer via a respective third and fourth pixel-driver interconnection (PDI) (772(1,2)), and further comprising forming the second front-plane layer (720) by: (2222) forming the third LED and the fourth LED on a second substrate (1409); (2224) depositing the second dielectric layer (1528) on the second substrate; and (2226) forming, in the second dielectric layer, a lower-third vertical subsegment (755(1)), a lower-fourth vertical subsegment (755(2)), and respective sections (1524(1,2)) of the third PDI and the fourth PDI each spanning a thickness of the second dielectric layer.

Embodiment 19. The method of Embodiment 18 further comprising, after hybrid-bonding (step 10, 2260) the second front-plane layer (1520) to the first spacer-dielectric layer (1318): (2272) removing the second substrate to expose a surface of the second dielectric layer; and (2274) electrically connecting (i) the lower-third vertical subsegment (755(1)) to the third LED and (ii) the lower-fourth vertical subsegment (755(2)) to the fourth LED by depositing respective conductive elements (756(1,2)) on the surface.

Embodiment 20. The method of Embodiment 18, further comprising: hybrid-bonding a third front-plane layer (730) to a second spacer-dielectric layer (1828) located on the second front-plane layer (720), the third front-plane layer including (i) a third dielectric layer (738), (ii) a fifth LED (734(1)) and a sixth LED (734(2)) embedded in the third dielectric layer and (iii) a fifth vertical subsegment (758(1)) and a sixth vertical subsegment (758(2)) each spanning a thickness (733) of the third dielectric layer; wherein hybrid-bonding the third front-plane layer includes: electrically connecting the fifth vertical subsegment (758(1)) to the lower-third vertical subsegment (755(1)); and electrically connecting the sixth vertical subsegment (758(2)) to the lower-fourth vertical subsegment (755(2)).

Embodiment 21. The method of Embodiment 20, the fifth and the sixth LED being electrically connected, respectively, to a fifth and a sixth driver circuit of the back-plane layer via a respective a fifth, and a sixth pixel-driver interconnection (PDI) (772(1,2), 773(1,2)), wherein forming the second front-plane layer (1010) further comprises: (2228) forming, in the second dielectric layer (1528) a lower-fifth vertical subsegment (1534(1)) and a lower-sixth vertical subsegment (1534(2)), and respective sections (1534(1,2)) of the fifth PDI, and the sixth PDI each spanning a thickness of the second dielectric layer.

Embodiment 22. The method of Embodiment 21, further comprising: (2316) depositing the second spacer-dielectric layer (1828) on the second dielectric layer (1528); (2318) forming, in the second spacer-dielectric layer (1828), an upper-third vertical subsegment (757(1)) that is electrically connected to the lower-third vertical subsegment (755(1)), an upper-fourth vertical subsegment (757(2)) that is electrically connected to the lower-fourth vertical subsegment (755(2)), and respective sections (1834(1,2)) of the fifth PDI and the sixth PDI each spanning a thickness of the second spacer-dielectric layer (1828).

Embodiment 23. The method of Embodiment 20, the fifth LED and the sixth LED being electrically connected, respectively, to a fifth and a sixth driver circuit of the back-plane layer via a respective fifth and a sixth pixel-driver interconnection (PDI) (773(1,2)), and further comprising forming the third front-plane layer (730) by: forming the fifth LED and the sixth LED on a third substrate (1909); depositing the third dielectric layer (738) on the third substrate; and forming, in the third dielectric layer, the fifth vertical subsegment (758(1)), the sixth vertical subsegment (758(2)), and respective sections (2034(1,2)) of the fifth PDI and the sixth PDI each spanning a thickness of the third dielectric layer.

Embodiment 24. The method of Embodiment 23 further comprising, after hybrid-bonding the third front-plane layer (730) to the second spacer-dielectric layer (1828): removing the third substrate (1909) to expose a surface of the third dielectric layer (738); and electrically connecting (i) the fifth vertical subsegment (758(1)) to the fifth LED and (ii) the sixth vertical subsegment (758(2)) to the sixth LED by depositing respective conductive elements (759(1,2)) on the surface.

Changes may be made in the above methods and systems without departing from the scope of the present embodiments. It should thus be noted that the matter contained in the above description or shown in the accompanying drawings should be interpreted as illustrative and not in a limiting sense. Herein, and unless otherwise indicated the phrase “in embodiments” is equivalent to the phrase “in certain embodiments,” and does not refer to all embodiments. The following claims are intended to cover all generic and specific features described herein, as well as all statements of the scope of the present method and system, which, as a matter of language, might be said to fall therebetween.

We claim:

1. A micro light-emitting diode (LED) display comprising:
a first pixel including a first LED, a third LED, and a first common-interconnection electrically connected to each of the first LED and the third LED;
a second pixel including a second LED, a fourth LED, and a second common-interconnection electrically connected to each of the second LED and the fourth LED; and
an opaque conductive element electrically connected to each of the first common-interconnection and the second common-interconnection.

2. The LED display of claim 1, further comprising a non-conductive transparent layer covering each of the first pixel and the second pixel.

3. The LED display of claim 1, further comprising a conductive transparent layer covering each of the first pixel and the second pixel and being electrically isolated from each of the first common-interconnection and the second common-interconnection.

4. The LED display of claim 1, the opaque conductive element being a ground plane or a common voltage plane.

5. The LED display of claim 1, the first pixel further including a first driver circuit electrically connected to the first LED, the second pixel further including a second driver circuit electrically connected to the second LED, and further comprising:
a front-plane layer that includes the first LED, the second LED, a first segment of the first common-interconnection, and a first segment of the second common-interconnection; and
a back-plane layer bonded to the front-plane layer and including the first driver circuit and the second driver circuit, a bottom section of the first common-interconnection, and a bottom section of the second common-interconnection.

6. The LED display of claim 5, the first pixel further including a third driver circuit electrically connected to the third LED, the second pixel further including a fourth driver circuit electrically connected to the fourth LED, and further comprising:
a second front-plane layer that includes the third LED, the fourth LED, a second segment of the first common-interconnection, and a second segment of the second common-interconnection; and
the back-plane layer further including the third driver circuit and the fourth driver circuit,
the first front-plane layer being between the second front-plane layer and the back-plane layer.

7. The LED display of claim 6,
the first segment of the first common-interconnection including a first vertical subsegment extending through the first front-plane layer and a first lateral section that extends from the first vertical subsegment to the first LED;
the second segment of the first common-interconnection including a third vertical subsegment extending through the second front-plane layer and a third horizontal section that extends from the third vertical subsegment to the third LED;
the first segment of the second common-interconnection including a second vertical subsegment extending through the first front-plane layer and a second lateral section that extends from the second vertical subsegment to the second LED; and
the second segment of the second common-interconnection including a fourth vertical subsegment extending through the second front-plane layer and a fourth lateral section that extends from the fourth vertical subsegment to the fourth LED.

8. The LED display of claim 1, the first pixel further including a fifth LED electrically connected to the first common-interconnection, the second pixel further including a sixth LED electrically connected to the second common-interconnection, and further comprising:
a third front-plane layer that includes the fifth LED, the sixth LED, a third segment of the first common-interconnection, and a third segment of the second common-interconnection,
the second front-plane layer being between the third front-plane layer and the first front-plane layer.

9. The LED display of claim 8,
the first segment of the first common-interconnection including a first vertical subsegment extending through the first front-plane layer and a first lateral section that extends from the first vertical subsegment to the first LED;
the second segment of the first common-interconnection including a third vertical subsegment extending through the second front-plane layer and a third lateral section that extends from the third vertical subsegment to the third LED;
the third segment of the first common-interconnection including a fifth vertical subsegment extending through the third front-plane layer and a fifth lateral section that extends from the fifth vertical subsegment to the fifth LED;
the first segment of the second common-interconnection including a second vertical subsegment extending through the first front-plane layer and a second lateral section that extends from the second vertical subsegment to the second LED;
the second segment of the second common-interconnection including a fourth vertical subsegment extending through the second front-plane layer and a fourth lateral section that extends from the fourth vertical subsegment to the fourth LED; and
the third segment of the second common-interconnection including a sixth vertical subsegment extending through the third front-plane layer and a sixth lateral section that extends from the sixth vertical subsegment to the sixth LED.

10. A LED display comprising:
a plurality of pixel pairs, each pixel pair of the plurality of pixel pairs including the first pixel of claim 1 and the second pixel of claim 1, such that the plurality of pixel pairs includes a plurality of first common-interconnections and a plurality of second common-interconnections;
each of the plurality of first common-interconnections being electrically isolated from (i) each other first common-interconnections of the plurality of first common-interconnections and (ii) each second common-interconnection of the plurality of second common-interconnections.

11. A method for fabricating an LED pixel-pair, comprising:
hybrid-bonding a first front-plane layer to a back-plane layer, the first front-plane layer including (i) a first dielectric layer, (ii) a first LED and a second LED embedded in the first dielectric layer, (iii) a lower-first vertical subsegment and a lower-second vertical subsegment each spanning a thickness of the first dielectric layer; and
hybrid-bonding a second front-plane layer to a first spacer-dielectric layer located on the first front-plane layer, the second front-plane layer including (i) a second dielectric layer, (ii) a third LED and a fourth LED embedded in the second dielectric layer and (iii) a third vertical subsegment and fourth vertical subsegment each spanning a thickness of the second dielectric layer.

12. The method of claim 11, hybrid-bonding the first front-plane layer to the back-plane layer comprising:
electrically connecting the lower-first vertical subsegment to a first back-plane interconnection segment of the back-plane layer; and
electrically connecting the lower-second vertical subsegment to a second back-plane interconnection segment, of the back-plane layer, that is electrically isolated from the lower-first vertical subsegment.

13. The method of claim 11, hybrid-bonding the first front-plane layer to the back-plane layer further comprising:
electrically connecting the first LED to a first driver circuit of the back-plane layer; and
electrically connecting the second LED to a second driver circuit of the back-plane layer.

14. The method of claim 11, hybrid-bonding the second front-plane layer to the first spacer-dielectric layer comprising:
electrically connecting the third vertical subsegment to the lower-first vertical subsegment; and
electrically connecting the fourth vertical subsegment to the lower-second vertical subsegment.

15. The method of claim 11, the first, the second, the third, and the fourth LED being electrically connected, respectively, to a first, a second, a third, and a fourth driver circuit of the back-plane layer via a respective first, a second, a third, and a fourth pixel-driver interconnection (PDI), and further comprising forming the first front-plane layer by:
forming the first LED and the second LED on a first substrate;
depositing the first dielectric layer on the first substrate; and
forming, in the first dielectric layer, a lower-first vertical subsegment, a lower-second vertical subsegment, and respective sections of the first PDI, the second PDI, the third PDI, and the fourth PDI each spanning a thickness of the first dielectric layer.

16. The method of claim 15, further comprising, after hybrid-bonding the first front-plane layer to the back-plane layer:
removing the first substrate to expose a surface of the first dielectric layer; and
electrically connecting (i) the lower-first vertical subsegment to the first LED and (ii) the lower-second vertical subsegment to the second LED by depositing respective conductive elements on the surface.

17. The method of claim 16, further comprising:
depositing the first spacer-dielectric layer on the first dielectric layer;
forming, in the first spacer-dielectric layer, an upper-first vertical subsegment that is electrically connected to the lower-first vertical subsegment, an upper-second vertical subsegment that is electrically connected to the lower-second vertical subsegment, and respective sections of the third PDI and the fourth PDI each spanning a thickness of the first spacer-dielectric layer.

18. The method of claim 11, the third and the fourth LED being electrically connected, respectively, to a third and a fourth driver circuit of the back-plane layer via a respective third and fourth pixel-driver interconnection (PDI), and further comprising forming the second front-plane layer by:
forming the third LED and the fourth LED on a second substrate;
depositing the second dielectric layer on the second substrate; and
forming, in the second dielectric layer, a lower-third vertical subsegment, a lower-fourth vertical subsegment, and respective sections of the third PDI and the fourth PDI each spanning a thickness of the second dielectric layer.

19. The method of claim 18 further comprising, after hybrid-bonding the second front-plane layer to the first spacer-dielectric layer:
removing the second substrate to expose a surface of the second dielectric layer; and
electrically connecting (i) the lower-third vertical subsegment to the third LED and (ii) the lower-fourth vertical subsegment to the fourth LED by depositing respective conductive elements on the surface.

20. The method of claim 18, further comprising:
hybrid-bonding a third front-plane layer to a second spacer-dielectric layer located on the second front-plane layer, the third front-plane layer including (i) a third dielectric layer, (ii) a fifth LED and a sixth LED embedded in the third dielectric layer and (iii) a fifth vertical subsegment and a sixth vertical subsegment each spanning a thickness of the third dielectric layer;
wherein hybrid-bonding the third front-plane layer includes:
electrically connecting the fifth vertical subsegment to the lower-third vertical subsegment; and
electrically connecting the sixth vertical subsegment to the lower-fourth vertical subsegment.

21. The method of claim 20, the fifth and the sixth LED being electrically connected, respectively, to a fifth and a sixth driver circuit of the back-plane layer via a respective a fifth, and a sixth pixel-driver interconnection (PDI), wherein forming the second front-plane layer further comprises:
forming, in the second dielectric layer a lower-fifth vertical subsegment and a lower-sixth vertical subsegment, and respective sections of the fifth PDI, and the sixth PDI each spanning a thickness of the second dielectric layer.

22. The method of claim 21, further comprising:
depositing the second spacer-dielectric layer on the second dielectric layer;
forming, in the second spacer-dielectric layer, an upper-third vertical subsegment that is electrically connected to the lower-third vertical subsegment, an upper-fourth vertical subsegment that is electrically connected to the lower-fourth vertical subsegment, and respective sections of the fifth PDI and the sixth PDI each spanning a thickness of the second spacer-dielectric layer.

23. The method of claim 20, the fifth LED and the sixth LED being electrically connected, respectively, to a fifth and a sixth driver circuit of the back-plane layer via a respective fifth and a sixth pixel-driver interconnection (PDI), and further comprising forming the third front-plane layer by:
forming the fifth LED and the sixth LED on a third substrate;
depositing the third dielectric layer on the third substrate; and
forming, in the third dielectric layer, the fifth vertical subsegment, the sixth vertical subsegment, and respective sections of the fifth PDI and the sixth PDI each spanning a thickness of the third dielectric layer.

24. The method of claim 23 further comprising, after hybrid-bonding the third front-plane layer to the second spacer-dielectric layer:
removing the third substrate to expose a surface of the third dielectric layer; and
electrically connecting (i) the fifth vertical subsegment to the fifth LED and (ii) the sixth vertical subsegment to the sixth LED by depositing respective conductive elements on the surface.
